(19) United States
(12) Patent Application Publication
(10) Pub. No.: US 2009/0135541 A1
(43) Pub. Date: May 28, 2009

(54) ACTUATOR AND ELECTRONIC CIRCUIT BASED THEREON

(75) Inventors: Takashi Kawakubo, Kanagawa-ken (JP); Toshihiko Nagano, Kanagawa-ken (JP); Michihiko Nishigaki, Kanagawa-ken (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/266,245

(22) Filed: Nov. 6, 2008

Related U.S. Application Data
(60) Provisional application No. 60/986,751, filed on Nov. 9, 2007.

(30) Foreign Application Priority Data
Nov. 6, 2007 (JP) 2007-288325

(51) Int. Cl. H01G 5/16; H01L 41/04

(52) U.S. Cl. 361/290; 310/366

(57) ABSTRACT

An actuator includes a substrate, a fixed electrode provided on a major surface of the substrate, a movable beam opposed to the major surface and held above the substrate with a gap thereto, and a dielectric film provided between the fixed electrode and the movable beam. The dielectric film is made of aluminum nitride oriented along c-axis with an orientation full width at half maximum of 4.6 degrees or less.

### CROSS-REFERENCE TO RELATED APPLICATIONS

This application is based upon and claims the benefit of priority from the prior Japanese Patent Application No. 2007-288325, filed on Nov. 6, 2007; the entire contents of which are incorporated herein by reference.

### BACKGROUND OF THE INVENTION

1. Field of the Invention

This invention relates to a MEMS (microelectromechanical system) actuator, such as a microswitch and a variable capacitor based on electrostatic or piezoelectric actuation, and to an electronic circuit based thereon.

2. Background Art

MEMS (microelectromechanical system) actuators are applied to microswitches and variable capacitors used in various optical switches, communication circuits, and electronic devices.

JP-A 2004-172504 (Kokai) discloses a MEMS actuator actuated by electrostatic force, which includes an electrostatic actuation mechanism illustratively composed of a movable electrode formed on a movable beam, a fixed electrode fixed on a substrate, and a dielectric film provided between the movable electrode and the fixed electrode. This dielectric film can be a silicon nitride or silicon oxide film widely used in conventional semiconductor processes, or any of various other films. However, no consideration is given to the degree of orientation of the film.

By application of an actuation voltage between the movable electrode and the fixed electrode, these electrodes are attracted by electrostatic force to move the movable electrode, thereby achieving actuation. During actuation, an actuation voltage of several ten volts is applied to the dielectric film having a thickness of approximately 0.1 to 1 μm or less, and hence the dielectric film is exposed to a high electric field. By this high electric field, electric charge is injected and trapped at the interface of or inside the dielectric film in accordance with the actuation time.

The injected charge exerts an effect similar to the externally applied actuation voltage on the electrostatic actuation mechanism, and hence significantly shifts the threshold voltage (pull-in voltage) for attaching the movable electrode to the fixed electrode and the threshold voltage (pull-out voltage) for releasing them. In more significant cases, the phenomenon called stiction occurs in which, even if the actuation voltage is reduced to zero, the electrodes remain stuck together and become inoperable. The shift of actuation voltage and the stiction phenomenon are serious problems in practice.

On the other hand, JP-A 2006-346830 (Kokai) discloses a MEMS actuator actuated by piezoelectric force, which uses a movable beam made of a piezoelectric film sandwiched between electrode layers and has an advantage that it can be actuated at a relatively low voltage. More specifically, the movable beam in such a piezoelectric MEMS actuator includes a piezoelectric actuation mechanism made of a piezoelectric film sandwiched between piezoelectric actuation electrode layers. It is known that in the piezoelectric MEMS actuator, the piezoelectric film constituting the movable beam can be illustratively made of an AlN film. The DC actuation voltage is applied between the piezoelectric actuation electrode layers sandwiching the piezoelectric film. Hence, charge injection/trapping, if any, into the piezoelectric film scarcely affects the actuation.

However, a variable capacitor device based on the piezoelectric MEMS actuator also includes a dielectric film, which forms the capacitance of the variable capacitor, between an RF signal-carrying fixed electrode formed on the substrate and a movable electrode provided on the movable beam (this electrode may be also used as a piezoelectric actuation electrode), and is based on a silicon nitride or silicon oxide film widely used in conventional semiconductor processes. When the RF signal-carrying fixed electrode is in contact with the movable electrode across the dielectric film, application of an RF voltage having a large amplitude between these electrodes causes charge injection and trapping into the dielectric film. In significant cases, the stiction phenomenon occurs in which, even if the piezoelectric actuation voltage is reduced to zero, the electrodes remain stuck together and become inoperable, causing a serious problem in practice.

On the other hand, IP-A 2006-019935 (Kokai) discloses a technique related to a thin film piezoelectric resonator. It is reported therein that the performance of a piezoelectric film can be improved by providing an Al—Ta amorphous alloy layer as a foundation of the piezoelectric film.

### SUMMARY OF THE INVENTION

According to an aspect of the Invention, there is provided an actuator including: a substrate; a fixed electrode provided on a major surface of the substrate; a movable beam opposed to the major surface and held above the substrate with a gap thereto; and a dielectric film provided between the fixed electrode and the movable beam and made of aluminum nitride oriented along c-axis with an orientation full width at half maximum of 4.6 degrees or less.

According to another aspect of the invention, there is provided an actuator including: a substrate; an RF signal-carrying fixed electrode provided on a major surface of the substrate; a movable beam opposed to the major surface and held above the substrate with a gap thereto, the movable beam including a DC actuated lower electrode, a piezoelectric film, and a DC actuated upper electrode; and a dielectric film provided between the RF signal-carrying fixed electrode and the movable beam and made of aluminum nitride oriented along c-axis with an orientation full width at half maximum of 4.6 degrees or less.

According to another aspect of the invention, there is provided an electronic circuit including: at least one of a switch and a variable capacitor made of an actuator, the actuator including: a substrate; a fixed electrode provided on a major surface of the substrate; a movable beam opposed to the major surface and held above the substrate with a gap thereto; and a dielectric film provided between the fixed electrode and the movable beam and made of aluminum nitride oriented along c-axis with an orientation full width at half maximum of 4.6 degrees or less.

According to another aspect of the invention, there is provided an electronic circuit including: a variable capacitor made of an actuator, the actuator including: a substrate; an RF signal-carrying fixed electrode provided on a major surface of the substrate; a movable beam opposed to the major surface and held above the substrate with a gap thereto, the movable beam including a DC actuated lower electrode, a piezoelectric film, and a DC actuated upper electrode; and a dielectric film provided between the RF signal-carrying fixed electrode and the movable beam and made of aluminum nitride oriented along c-axis with an orientation full width at half maximum of 4.6 degrees or less.

### BRIEF DESCRIPTION OF THE DRAWINGS

FIG. 1 is a cross-sectional schematic view illustrating the configuration of an actuator according to a first embodiment of the invention;

FIGS. 2(a) to 2(c) illustrate the relationship between the degree of orientation of the dielectric film and the amount of charge injected into the dielectric film;

FIGS. 3A to 3D are schematic cross-sectional views showing the steps of a method for manufacturing the actuator of Example 1 of the invention;

FIG. 4 illustrates the operation test condition for the actuator of the Examples of the invention;

FIG. 5 is a graph showing the operation test result for the actuator of Examples 1-4 of the invention;

FIG. 6 is a schematic cross-sectional view illustrating the structure of the actuator of Example 5 of the invention;

FIG. 7 is a schematic cross-sectional view illustrating the structure of the actuator of Example 6 of the invention;

FIG. 8 is a schematic cross-sectional view illustrating the structure of the actuator of Example 7 of the invention;

FIG. 9 is a schematic cross-sectional view illustrating the structure of the actuator of Example 8 of the invention; and

FIG. 10 is a schematic view illustrating an electronic circuit and an electronic device based on the actuator of the embodiment of the invention.

### DETAILED DESCRIPTION OF THE INVENTION

An embodiment of the invention will now be described in detail with reference to the drawings.

### First Embodiment

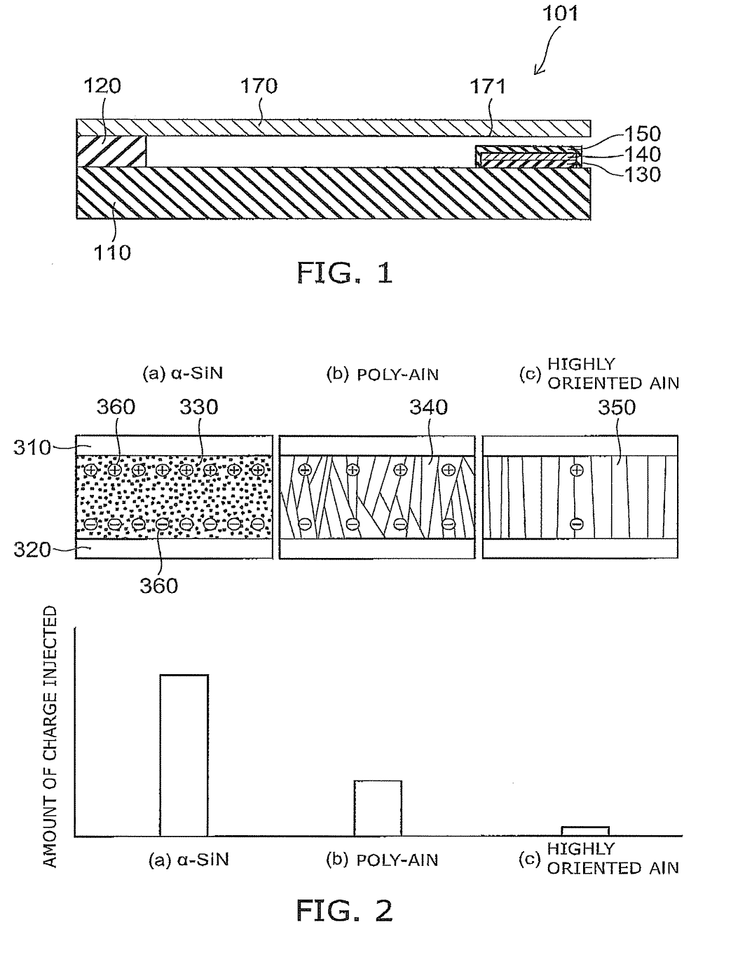

FIG. 1 is a cross-sectional schematic view illustrating the configuration of an actuator according to a first embodiment of the invention.

As shown in FIG. 1, the actuator 101 of the first embodiment of the invention includes a substrate 110. A foundation film 130 is provided on the major surface of the substrate 110, a fixed electrode 140 is provided on the foundation film 130, and a dielectric film 150 is further provided on the fixed electrode 140. The foundation film 130 can illustratively be a film made of an aluminum/tantalum (Al/Ta) amorphous alloy or aluminum nitride (AlN). The fixed electrode 140 can be a film made of aluminum. The dielectric film 150 can be an aluminum nitride film oriented along the c-axis with a small orientation full width at half maximum.

A movable beam 170 is opposed to the major surface of the substrate 110 with a gap thereto. Part of the movable beam 170 is bonded by an anchor portion 120 provided on the substrate 110, and the anchor portion 120 allows the movable beam 170 to be held with the gap to the substrate 110.

In the actuator shown in FIG. 1, the foundation film 130 is a film made of an aluminum/tantalum amorphous alloy or aluminum nitride, which can increase the degree of orientation of the fixed electrode 140 provided thereon. Specifically, <111> axis orientation with an orientation full width at half maximum of 5 degrees or less is obtained. Furthermore, the dielectric film 150 provided on the fixed electrode 140 is also highly oriented, and c-axis orientation with an orientation full width at half maximum of 5 degrees or less is obtained.

If the orientation full width at half maximum of the dielectric film 150 is decreased to achieve a high degree of orientation, the density of charge traps in the dielectric film 150 decreases. Consequently, charge injection and charge trapping into the dielectric film 150 can be prevented. This mechanism is described with reference to FIG. 2.

FIG. 2 illustrates the relationship between the degree of orientation of the dielectric film and the amount of charge injected into the dielectric film.

As shown in FIG. 2(a), an amorphous silicon nitride (α-SiN) film 330 has many dangling bonds acting as traps. By application of a voltage to this α-SiN film sandwiched between an upper electrode 310 and a lower electrode 320, a large amount of charge 360 is injected and trapped. On the other hand, as shown in FIG. 2(b), a polycrystalline aluminum nitride (poly-AlN) film 340 has a relatively large crystal sizes and grain boundaries are decreased. Hence, the amount of injected charge 360 decreases. Furthermore, as shown in FIG. 2(c), in a highly oriented aluminum nitride film 350, grain boundaries are further decreased, and the amount of injected charge 360 can be made extremely small. Thus, to reduce charge injection into the dielectric film, it is favorable to decrease grain boundaries in the dielectric film to reduce traps. That is, charge injection can be prevented by decreasing the orientation full width at half maximum of the dielectric film.

In the actuator illustrated in FIG. 1, the foundation film 130 is a film made of an aluminum/tantalum amorphous alloy or aluminum nitride. Thus, the degree of orientation of the dielectric film 150 can be increased, charge injection is less likely to occur upon application of a voltage, and formation of charge traps is prevented. Consequently, an actuator having good operational stability can be realized.

Here, to ensure practical operational stability, the orientation full width at half maximum of the dielectric film 150 made of AlN is preferably 5 degrees or less.

The highly oriented AlN film can be formed illustratively by using an amorphous metal foundation. It is also possible to use a method of epitaxial growth on a single crystal substrate such as a silicon (111) substrate and a silicon (100) substrate so that its orientation is inherited. Furthermore, there is also a method of growing a highly oriented AlN on a highly oriented foundation film so that its orientation is inherited. The foundation film in this case can be made of various metals or insulating films. For example, it is possible to use the (111) plane of the fcc crystal structure of Al, Au and the like, the (110) plane of the bcc crystal structure of Mo, W, Ta and the like, and the (0001) plane of the hexagonal crystal structure of Ti, AlN and the like. In these methods, the degree of orientation of the AlN film is affected by the crystal orientation of the foundation material. As the foundation material becomes thick, the degree of orientation of the AlN film increases. Furthermore, the above techniques can be combined with each other.

A movable electrode 171 can be provided on the portion of the movable beam 170 opposed to the fixed electrode 140. However, in the case where the movable beam 170 is conductive, the movable beam 170 itself can be used as a movable electrode 171. The actuator illustrated in FIG. 1 is such an example. In this case, the movable electrode 171 is identical to the movable beam 170. Alternatively, a movable electrode 171 can be separately provided on the movable beam 170.

The dielectric film 150 does not need to be located on the substrate 110, but only needs to be provided between the fixed electrode 140 and the movable electrode 171 (movable beam 170). For example, the dielectric film 150 can be provided on the portion of the movable beam 170 opposed to the fixed electrode 140. In the case of a piezoelectric actuator in which the movable beam 170 has a piezoelectric laminated structure, the piezoelectric film can be made of AlN, which can be used as a dielectric film 150.

The actuator illustrated in FIG. 1 can be used as a microswitch and a capacitor. Besides the movable electrode 171 (movable beam 170) and the fixed electrode 140, various electrodes can be additionally provided and used to constitute a switch and a capacitor.

In this disclosure, the “actuator” refers to not only the movable portion, but also to any of various switches or various capacitors including the movable portion.

### Example 1

In the following, the embodiment is described in detail with reference to Example 1.

The actuator of Example 1 of the invention has a structure shown in FIG. 1. That is, a foundation film 130, a fixed electrode 140, and a dielectric film 150 are laminated on the major surface of a substrate 110. A movable beam 170 is held by an anchor portion 120 so as to be opposed to the major surface of the substrate 110 with a gap thereto.

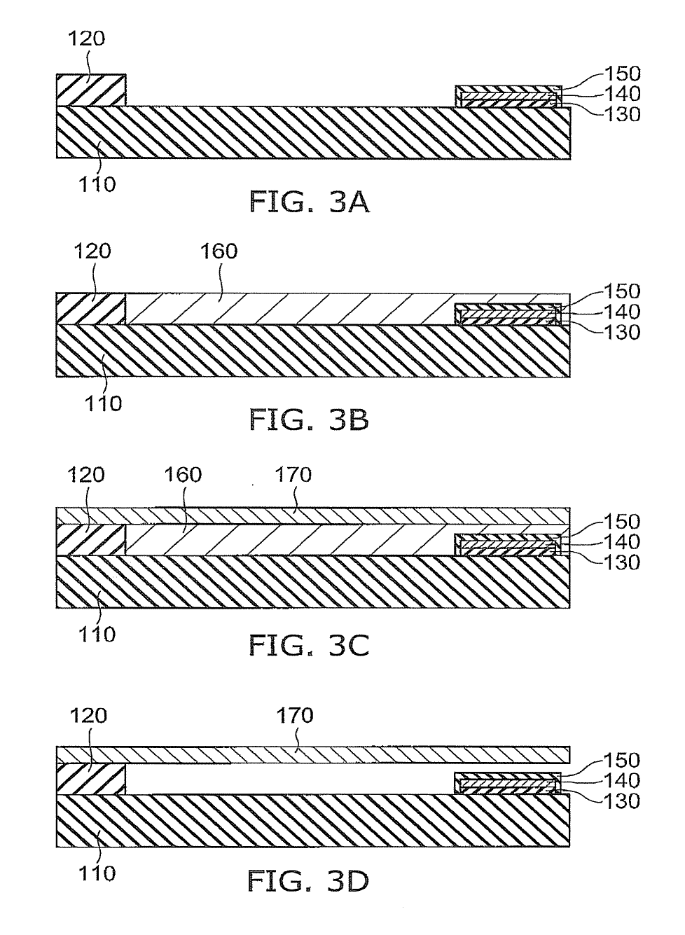

FIG. 3 is a schematic cross-sectional view showing the steps of a method for manufacturing the actuator of Example 1 of the invention.

First, as shown in FIG. 3A, a silicon nitride film was formed on the major surface of a substrate 110 having an insulative surface by LP-CVD (low pressure chemical vapor deposition) to form an anchor portion 120.

Furthermore, a foundation film 130, a fixed electrode 140, and a dielectric film 150 were formed in this order on another portion of the major surface of the substrate 110. More specifically, an amorphous alloy film made of Al/Ta and having a thickness of 30 nm was formed as a foundation film 130 by sputtering. Subsequently, an Al film having a thickness of 500 nm was formed as a fixed electrode 140 by sputtering. Subsequently, an AlN film having a thickness of 500 nm was formed as a dielectric film 150 by sputtering. Then, the anchor portion 120, the foundation film 130, the fixed electrode 140, and the dielectric film 150 described above were formed into a prescribed shape by lithography and reactive ion etching (RIE), The methods for film formation and shaping are not limited to the methods described above, but various other methods can be used.

Next, as shown in FIG. 3B, a sacrificial layer 160 was formed on the major surface of the substrate 110, the anchor portion 120, and the dielectric film 150. Then, the surface was polished and planarized by the CMP (chemical mechanical polishing) technique to expose the anchor portion 120. The sacrificial layer 160 was made of polycrystalline silicon. However, the sacrificial layer 160 is not limited thereto, but can be made of various inorganic materials, various metal materials, and various organic materials, which can be selectively etched with respect to the above materials of the other films such as the foundation film 130, the fixed electrode 140, and the dielectric film 150.

Next, as shown in FIG. 3C, a movable beam 170 was formed on the anchor portion 120 and the sacrificial layer 160. Specifically, an Al layer having a thickness of 500 nm was formed by sputtering, and patterned by lithography and etching to form a movable beam 170 having a prescribed shape.

Next, as shown in FIG. 3D, the sacrificial layer 160 was removed by selective etching using XeF₂ as an etching gas.

Thus, the actuator having a structure shown in FIG. 1 was fabricated.

In the actuator of Example 1 having such a structure, the foundation film is made of an Al/Ta amorphous alloy. Hence, the fixed electrode 140 can be highly oriented in the (111) orientation. The degree of orientation of the fixed electrode 140 was measured by the ω mode-locking curve technique. The orientation full width at half maximum (FWHM) was very small, 0.9 degrees. Thus, a high degree of orientation was confirmed. Furthermore, by heteroepitaxial growth of an AlN layer to serve as a dielectric film 150 on the fixed electrode 140, the AlN layer was highly oriented along the c-axis. The orientation full width at half maximum measured by the ω mode-locking curve technique was 1.6 degrees. Thus, by using an Al/Ta amorphous alloy for the foundation film, a dielectric film 150 made of an AlN film with high degree of orientation was obtained.

### Examples 2-4

Next, Examples 2-4 are described.

Examples 2-4 are different from Example 1 in that the foundation film 130 is made of AlN, but the other conditions are the same as in Example 1. The thickness of the foundation film 130 in Examples 2-4 was 1000 nm, 500 nm, and 200 nm, respectively. In the actuator of these Examples 2-4, the foundation film 130 is made of an AlN film having a thickness of 200 to 1000 nm. Thus, a fixed electrode 140 and a dielectric film 150 with high degree of orientation can be provided.

TABLE 1 shows the type and thickness of the foundation film 130 in relation to the orientation full width at half maximum of the fixed electrode 140 and the dielectric film 150 described above with reference to Examples 1-4

TABLE 1

| | Type of | Thickness of | Orientation FWHM | Orientation FWHM |
|---|---|---|---|---|
| | Foundation Film | Foundation Film | of Fixed Electrode | of Dielectric Film |
| Example 1 | Al/Ta | 30 nm | 0.9 degree | 1.6 degree |
| | amorphous alloy | | | |
| Example 2 | AlN | 1000 nm | 1.9 degree | 2.8 degree |
| Example 3 | AlN | 500 nm | 2.4 degree | 3.5 degree |
| Example 4 | AlN | 200 nm | 3.8 degree | 4.6 degree |

As shown in TABLE 1, in the actuator of Examples 1-4, the orientation full width at half maximum of the dielectric film 150 was 1.6 to 4.6 degrees, exhibiting very high degree of orientation. The orientation full width at half maximum of the fixed electrode 140 was 0.9 to 3.8 degrees, also exhibiting very high degree of orientation.

Next, an operation test was performed on the actuator of Examples 1-4 thus fabricated.

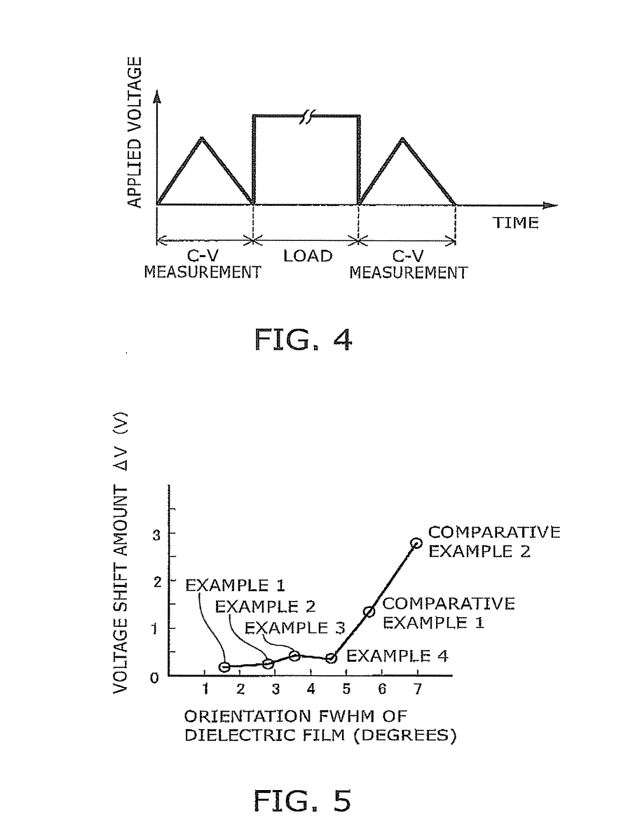

FIG. 4 illustrates the operation test condition for the actuator of the Examples of the invention.

The operation test was performed by the following method as shown in FIG. 4.

(1) First, voltage is gradually applied between the fixed electrode 140 and the movable electrode 171 (movable beam 170) to measure the capacitance versus applied voltage characteristics (C-V measurement) and measure the initial value of the pull-in voltage at which the movable beam 170 is brought into contact with the dielectric film 150.

(2) Subsequently, an actuation voltage of 15 V is applied as a load for 1000 seconds, and the actuation voltage is stopped.

(3) Subsequently, voltage is gradually applied again to perform C-V measurement to measure the pull-in voltage after the load test.

Thus, the change (shift amount ΔV) of the pull-in voltage before and after the load test was determined.

A description is given of the relationship between the orientation full width at half maximum of the dielectric film 150 of Examples 1-4 and the shift amount ΔV of the pull-in voltage before and after the load test.

FIG. 5 is a graph showing the operation test result for the actuator of Examples 1-4 of the invention.

As shown in FIG. 5, in any of the actuators of Examples 1-4, the orientation full width at half maximum of the dielectric film 150 was 5 degrees or less, and the shift amount ΔV of the pull-in voltage was 0.5 V or less. Thus, it was confirmed that the actuator of Examples 1-4 has good operational stability.

Next, comparative examples are described.

### Comparative Examples 1-2

The actuator of Comparative Example 1 is different from the actuator shown in FIG. 1 in that the foundation film 130 is made of AlN having a thickness of 100 nm. Comparative Example 2 has a structure with no foundation film.

TABLE 2 shows the type and thickness of the foundation film 130 and the orientation full width at half maximum of the fixed electrode 140 and the dielectric film 150 with regard to the actuator of Comparative Examples 1 and 2.

TABLE 2

| | Type of | Thickness of | Orientation FWHM | Orientation FWHM |
|---|---|---|---|---|
| | Foundation Film | Foundation Film | of Fixed Electrode | of Dielectric Film |
| Comparative | AlN | 100 nm | 5.1 degree | 5.8 degree |
| Example 1 | | | | |
| Comparative | none | — | 6.2 degree | 7.0 degree |
| Example 2 | | | | |

As shown in TABLE 2, in the actuator of Comparative Example 1, the thickness of the foundation film 130 is small, and the orientation full width at half maximum of the fixed electrode 140 and the dielectric film 150 provided thereon were 5.1 and 5.8 degrees, respectively, both exhibiting large values. The actuator of Comparative Example 2 has no foundation film 130, and the orientation full width at half maximum of the fixed electrode 140 and the dielectric film 150 were 6.2 and 7.0 degrees, respectively, exhibiting even larger values. Thus, in the case where there was no foundation film or the thickness of the foundation film was small, the orientation full width at half maximum of the dielectric film 150 was increased, and the degree of orientation of the dielectric film 150 was decreased.

Furthermore, under a test condition similar to that for Examples 1-4 (except that the application time of the load voltage was reduced to 100 seconds), the shift amount ΔV of the pull-in voltage before and after the load test was determined for Comparative Examples 1 and 2. The result is shown in FIG. 5. Although the application time of the load voltage was reduced to 1/10 of that for Examples 1-4 to alleviate the load, the shift amount ΔV of the pull-in voltage was as large as 1.5 V in Comparative Example 1, indicating a problem in the reliability of the actuator. In Comparative Example 2, the shift amount ΔV of the pull-in voltage was even larger, 3.1 V, likewise indicating a problem in the reliability of the actuator.

As shown in FIG. 5, when the orientation full width at half maximum of the dielectric film 150 is larger than 5 degrees, the shift amount ΔV of the pull-in voltage is sharply increased. Hence, the orientation full width at half maximum of the dielectric film 150 is preferably 4.6 degrees or less. Furthermore, as shown in TABLE 1, the orientation full width at half maximum of the fixed electrode 140 in this case is preferably 3.8 degrees or less. In the case where the foundation film 130 is made of AlN, the thickness of the AlN film needs to be larger than a certain level. Specifically, the thickness is preferably 200 nm or more.

### Comparative Example 3

The actuator of Comparative Example 3 is the same as the actuator of Example 1 except that the dielectric film 150 is a silicon nitride film formed by LP-CVD.

Under a test condition similar to that for Examples 1-4 (except that the application time of the load voltage was reduced to 100 seconds), the shift amount ΔV of the pull-in voltage in Comparative Example 3 was determined. The result was that, although the application time of the load voltage was reduced to 1/10 of that for Examples 1-4 to alleviate the load, the shift amount ΔV of the actuator of Comparative Example 3 was as large as 6.7 V. Thus, a significant level of charge Injection occurred, indicating a problem in the stability of operation. This is because the silicon nitride film has numerous traps for electric charge, and hence a large amount of charge is injected and trapped into the silicon nitride dielectric film. Thus, the dielectric film 150 is preferably made of an AlN material.

### Example 5

Next, an actuator of Example 5 of the invention is described. The actuator of Example 5 is an example of an electrostatically actuated MEMS switch, which separately includes a switching contact electrode.

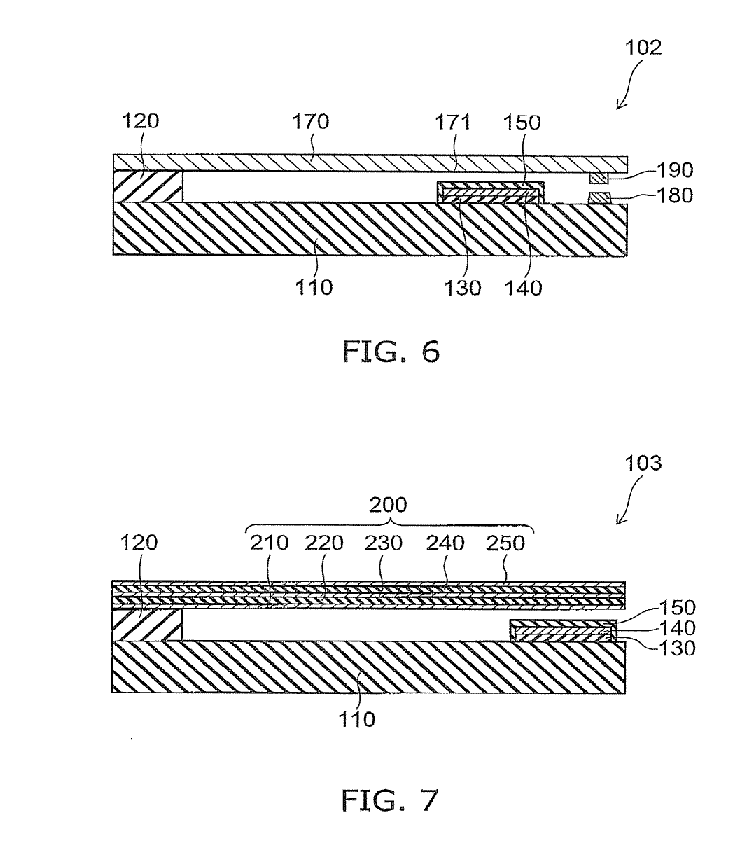

FIG. 6 is a schematic cross-sectional view illustrating the structure of the actuator of Example 5 of the invention. The actuator 102 of this Example has a movable contact electrode 190 at the tip of the movable beam 170. A fixed contact electrode 180 opposed to the movable contact electrode 190 is provided on the substrate 110. The movable contact electrode 190 and the fixed contact electrode 180 constitute the contact of a switch. The configuration other than the foregoing is the same as that of Example 1, and like components are labeled with like reference numerals. The movable contact electrode 190 and the fixed contact electrode 180 are illustratively Au layers fabricated by sputtering, which are patterned by conventional lithography and lift-off techniques.

The actuator is actuated by application of a voltage between the fixed electrode 140 and the movable electrode 171 (movable beam 170) opposed thereto. At this time, the movable contact electrode 190 and the fixed contact electrode 180 are brought into ohmic contact with each other, and can be used as a radio-frequency (RF) switch.

The shift amount ΔV of the pull-in voltage, measured under the same test condition as in Examples 1-4, was as small as 0.3 V. Thus, stable operation was confirmed.

### Example 6

Next, an actuator of Example 6 of the invention is described. The actuator of this Example is an example of a piezoelectrically actuated MEMS variable capacitor.

FIG. 7 is a schematic cross-sectional view illustrating the structure of the actuator of Example 6 of the invention.

As shown in FIG. 7, the actuator 103 of Example 6 uses a movable beam 200 made of a bimorph piezoelectric actuator instead of the movable beam 170 in Example 1. That is, a bimorph piezoelectric movable beam 200 is provided above the substrate 110 and opposed thereto. The bimorph movable beam 200 has a structure in which a lower electrode 210, a lower piezoelectric film 220, an intermediate electrode 230, an upper piezoelectric film 240, and an upper electrode 250 are laminated. The bimorph movable beam 200 is held by the anchor portion 120 with a gap to the substrate 110. The lower electrode 210, the intermediate electrode 230, and the upper electrode 250 are made of Al, and the lower piezoelectric film 220 and the upper piezoelectric film 240 are made of AlN. They are formed into a prescribed shape by lithography and etching techniques. The configuration other than the bimorph movable beam 200 is the same as that of Example 1. The fixed electrode 140 and the dielectric electrode 150 are a highly oriented Al film and AlN film.

In the actuator 103 of this Example, the piezoelectric movable beam 200 can be vertically bent by grounding the intermediate electrode 230 and applying an actuation voltage to the lower electrode 210 and the upper electrode 250. This bending varies the distance between the fixed electrode 140 provided on the substrate 110 and the lower electrode 210, and the actuator 103 serves as a variable capacitor.

Here, the lower electrode 210 serves as a movable electrode 171 opposed to the fixed electrode 140.

In this Example, the voltage (contact voltage) at the time when the piezoelectric movable beam 210 is bent downward to bring the lower electrode 210 into contact with the dielectric electrode 150 was 2.8 V. With the lower electrode 210 being in contact with the dielectric electrode 150, an AC voltage having an amplitude of 10 V was applied between the fixed electrode 140 and the lower electrode 210 for 100 seconds, and the AC voltage was stopped. The contact voltage subsequently measured by sweeping the piezoelectric actuation voltage was 2.9 V, exhibiting little shift from the initial value of the contact voltage. Thus, stable operation was confirmed.

In this Example, the movable beam has a structure in which two piezoelectric films are laminated with three electrodes. However, the movable beam is not limited thereto, but can be based on various structures, such as a structure in which one piezoelectric film is sandwiched between two electrodes, and a structure in which three or more piezoelectric films are each sandwiched between electrodes.

In this Example, the lower electrode 210, the intermediate electrode 230, and the lower piezoelectric film 220 serve as a DC actuated lower electrode, a DC actuated upper electrode, and a piezoelectric film, respectively. The intermediate electrode 230, the upper electrode 250, and the upper piezoelectric film 240 serve as another DC actuated lower electrode, another DC actuated upper electrode, and another piezoelectric film, respectively. The fixed electrode 150 serves as an RF signal-carrying fixed electrode.

### Example 7

Next, an actuator of Example 7 of the invention is described.

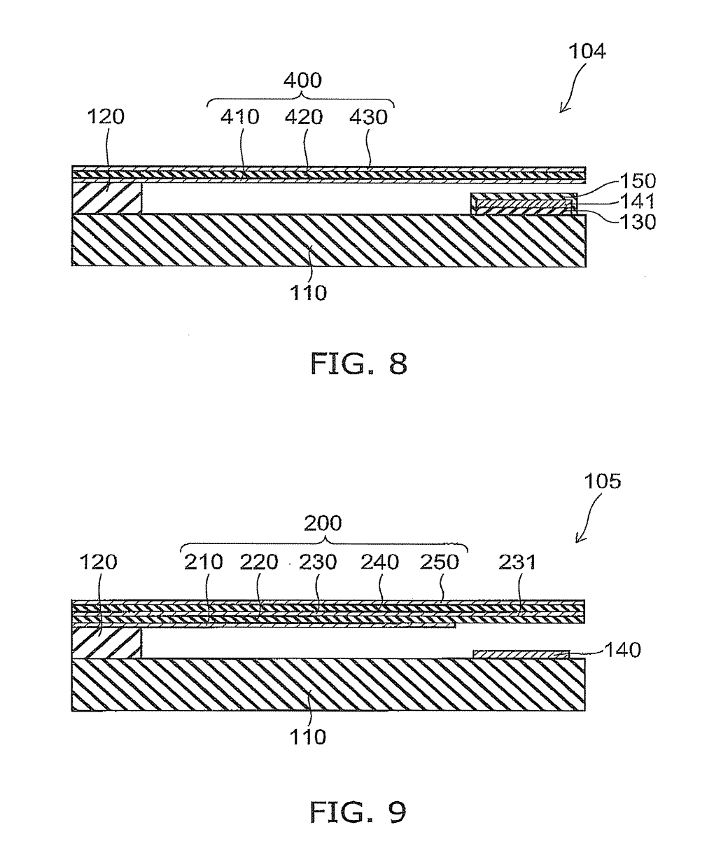

FIG. 8 is a schematic cross-sectional view illustrating the structure of the actuator of Example 7 of the invention.

As shown in FIG. 8, the actuator 104 of Example 7 uses, instead of the movable beam 170 in Example 1 shown in FIG. 1, a movable beam 400 having a configuration in which a DC actuated lower electrode 410, a piezoelectric film 420, and a DC actuated upper electrode 430 are laminated. An RF signal-carrying fixed electrode 141 is provided on the major surface of the substrate 110 via a foundation layer 130, and a dielectric film 150 is provided between the RF signal-carrying fixed electrode 141 and the movable beam 400. The foundation layer 130, the RF signal-carrying fixed electrode 141, and the dielectric film 150 can be the same as the foundation layer 130, the fixed electrode 140, and the dielectric film 150 illustrated in FIG. 1.

In the actuator 104, the movable beam 400 is bent by application of an actuation voltage between the DC actuated lower electrode 410 and the DC actuated upper electrode 430 and application of a voltage to the piezoelectric film 420. Thus, the DC actuated lower electrode 410 is brought into contact with the dielectric film 150, forming a capacitor between the DC actuated lower electrode 410 and the RF signal-carrying fixed electrode 141 across the dielectric film 150.

In this Example, the dielectric film 150 is made of a highly oriented AlN film (oriented along the c-axis with an orientation full width at half maximum of 4.6 degrees or less). Hence, charge injection and trapping into the dielectric film 150 can be prevented, and an actuator having stable actuation characteristics can be realized.

### Example 8

Next, an actuator of Example 8 of the invention is described.

FIG. 9 is a schematic cross-sectional view illustrating the structure of the actuator of Example 8 of the invention.

As shown in FIG. 9, the actuator 105 of Example 8 is different from the actuator of Example 6 shown in FIG. 7 in that the foundation film 130 and the dielectric film 150 provided below and above the fixed electrode 140 are omitted, and that the lower electrode 210 is formed excluding the portion opposed to the fixed electrode 140. In this configuration, the lower piezoelectric film 220 opposed to the fixed electrode 140 serves as the dielectric film in Examples 1-7. The intermediate electrode 230 serves as a movable electrode 231.

The lower piezoelectric film 220 can be formed from a highly oriented AlN film (oriented along the c-axis with an orientation full width at half maximum of 4.6 degrees or less). In the actuator illustrated in FIG. 9, the dielectric film made of a highly oriented AlN film is provided between the fixed electrode 140 and the movable electrode 231. Hence, charge injection and trapping into the dielectric film can be prevented, and an actuator having stable actuation characteristics can be realized.

The actuator of the embodiment and Examples of the invention described above can be used to form a microswitch or a variable capacitor, which can be used to fabricate various electronic circuits.

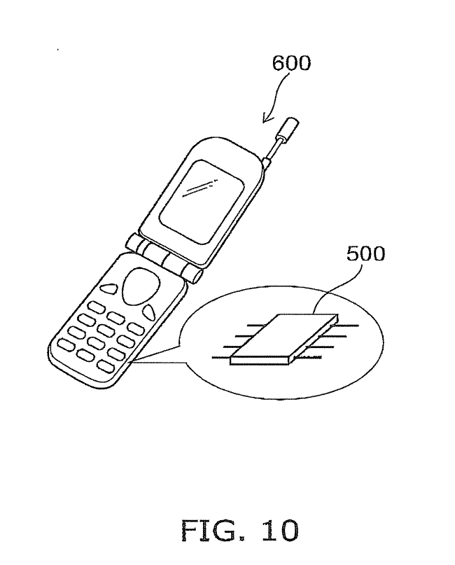

FIG. 10 is a schematic view illustrating an electronic circuit and an electronic device based on the actuator of the embodiment of the invention.

As shown in FIG. 10, an electronic circuit 500 including a variable frequency filter can be fabricated by incorporating a variable capacitor based on the actuator 105 of the embodiment of the invention. This electronic circuit 500 can be illustratively used in various electronic devices 600 such as cell phones.

The embodiment of the invention has been described with reference to specific examples. However, the invention is not limited to these specific examples. For Instance, the specific configurations of the components constituting the actuator can be suitably selected from conventional ones by those skilled in the art, and such configurations are encompassed within the scope of the invention as long as they can also implement the invention and achieve similar effects.

Components in two or more of the specific examples can be combined with each other as long as technically feasible, and such combinations are also encompassed within the scope of the invention as long as they fall within the spirit of the invention.

The actuators described above as the embodiment of the invention can be suitably modified and practiced by those skilled in the art, and such modifications are also encompassed within the scope of the invention as long as they fall within the spirit of the invention.

Various other variations and modifications can be conceived by those skilled in the art within the spirit of the invention, and it is understood that such variations and modifications are also encompassed within the scope of the invention.

1. An actuator comprising:
a substrate;
a fixed electrode provided on a major surface of the substrate;
a movable beam opposed to the major surface and held above the substrate with a gap thereto; and
a dielectric film provided between the fixed electrode and the movable beam and made of aluminum nitride oriented along c-axis with an orientation full width at half maximum of 4.6 degrees or less.

2. The actuator according to claim 1, further comprising:
a foundation film provided below the fixed electrode and made of an aluminum compound.

3. The actuator according to claim 2, wherein the aluminum compound is one selected from AlN, an Al—Ta amorphous alloy, and a mixture thereof.

4. The actuator according to claim 2, wherein the foundation film is a film made of AlN having a thickness of 200 nm or more.

5. The actuator according to claim 1, wherein the fixed electrode is made of an aluminum film oriented along c-axis with an orientation full width at half maximum of 3.8 degrees or less.

6. The actuator according to claim 1, wherein the dielectric film is provided on at least one of a movable electrode provided on the movable beam, and the fixed electrode.

7. The actuator according to claim 1, further comprising:
a movable contact provided at least one of the substrate and the movable beam.

8. The actuator according to claim 1, wherein the movable beam includes a lower electrode, an upper electrode opposed to the lower electrode, an intermediate electrode provided between the lower electrode and the upper electrode, a lower piezoelectric film provided between the lower electrode and the intermediate electrode, and an upper piezoelectric film provided between the upper electrode and the intermediate electrode.

9. The actuator according to claim 1, wherein the movable beam includes a lower electrode, an upper electrode opposed to the lower electrode, and a piezoelectric film provided between the lower electrode and the upper electrode.

10. An actuator comprising:
a substrate;
an RF signal-carrying fixed electrode provided on a major surface of the substrate;
a movable beam opposed to the major surface and held above the substrate with a gap thereto, the movable beam including a DC actuated lower electrode, a piezoelectric film, and a DC actuated upper electrode; and
a dielectric film provided between the RF signal-carrying fixed electrode and the movable beam and made of aluminum nitride oriented along c-axis with an orientation full width at half maximum of 4.6 degrees or less.

11. The actuator according to claim 10, further comprising:
a foundation film provided below the fixed electrode and made of an aluminum compound.

12. The actuator according to claim 11, wherein the aluminum compound is one selected from AlN, an Al—Ta amorphous alloy, and a mixture thereof.

13. The actuator according to claim 11, wherein the foundation film is a film made of AlN having a thickness of 200 nm or more.

14. The actuator according to claim 10, wherein the fixed electrode is made of an aluminum film oriented along c-axis with an orientation full width at half maximum of 3.8 degrees or less.

15. The actuator according to claim 10, wherein the dielectric film is provided on at least one of a movable electrode provided on the movable beam, and the fixed electrode.

16. The actuator according to claim 10, further comprising:
a movable contact provided at least one of the substrate and the movable beam.

17. The actuator according to claim 10, wherein the movable beam includes a lower electrode, an upper electrode opposed to the lower electrode, an intermediate electrode provided between the lower electrode and the upper electrode, a lower piezoelectric film provided between the lower electrode and the intermediate electrode, and an upper piezoelectric film provided between the upper electrode and the intermediate electrode.

18. The actuator according to claim 10, wherein the movable beam includes a lower electrode, an upper electrode opposed to the lower electrode, and a piezoelectric film provided between the lower electrode and the upper electrode.

19. An electronic circuit comprising:
at least one of a switch and a variable capacitor made of an actuator, the actuator including:
a substrate;
a fixed electrode provided on a major surface of the substrate;
a movable beam opposed to the major surface and held above the substrate with a gap thereto; and
a dielectric film provided between the fixed electrode and the movable beam and made of aluminum nitride oriented along c-axis with an orientation full width at half maximum of 4.6 degrees or less.

20. An electronic circuit comprising:
a variable capacitor made of an actuator, the actuator including:
a substrate;
an RF signal-carrying fixed electrode provided on a major surface of the substrate;
a movable beam opposed to the major surface and held above the substrate with a gap thereto, the movable beam including a DC actuated lower electrode, a piezoelectric film, and a DC actuated upper electrode; and
a dielectric film provided between the RF signal-carrying fixed electrode and the movable beam and made of aluminum nitride oriented along c-axis with an orientation full width at half maximum of 4.6 degrees or less.
